(19) United States
(12) Patent Application Publication
(10) Pub. No.: US 2012/0188700 A1
(43) Pub. Date: Jul. 26, 2012

(54) DOCKING STATION AND ELECTRONIC APPARATUS USING THE SAME

(75) Inventors: Wen-Hsien Chiang, Taipei City (TW); Yung-Hsiang Chen, Taipei City (TW); Hsin Lu, Taipei City (TW); Cheng-Min Huang, Taipei City (TW); Hsin Yeh, Taipei City (TW); Hsiang-Ling Liu, Taipei City (TW)

(73) Assignee: COMPAL ELECTRONICS, INC., Taipei City (TW)

(21) Appl. No.: 13/349,589

(22) Filed: Jan. 13, 2012

Related U.S. Application Data
(60) Provisional application No. 61/435,787, filed on Jan. 25, 2011.

(51) Int. Cl. H05K 7/00; G06F 1/16

(52) U.S. Cl. 361/679.26; 361/679.01

(57) ABSTRACT

An electronic apparatus including a portable device and a docking station is provided. The portable device has a display surface and the first restricting element. The docking station includes a base having a supporting surface and the second restricting element disposed on the supporting surface. The first restricting element is latched to the second restricting element when the portable device is attached to the supporting surface. Besides, the portable device is adapted to stand on the base by restricting the relative position of the portable device and the second restricting element.

### CROSS-REFERENCE TO RELATED APPLICATION

This application claims the priority benefits of U.S. provisional application Ser. No. 61/435,787, filed on Jan. 25, 2011. The entirety of the above-mentioned patent applications is hereby incorporated by reference herein and made a part of this specification.

### BACKGROUND OF THE INVENTION

1. Field of the Invention

The present invention generally relates to an electronic apparatus. More particularly, the present invention relates to a docking station and an electronic apparatus using the same.

2. Description of Related Art

Along with the development of technology, portable electronic devices, such as tablet personal computers (tablet PC) and electronic readers (E-Reader), are now in widespread use. In general, control information is input to a conventional tablet personal computer through a touch screen. However, operation convenience of the touch screen does not satisfy all of the user's demands, so that a related docking station is developed accordingly. However, the operation process of the docking station is complicated and the price is high. Therefore, it is an important issue of the computer industry to provide a docking station with a good attachment and improve operation convenience of the docking station and the portable electronic device.

### SUMMARY OF THE INVENTION

The present invention provides an electronic apparatus including a portable device and a docking station. The portable device has a display surface and a first restricting element. The docking station includes a base having a supporting surface and a second restricting element disposed on the supporting surface. Herein the first restricting element is latched to the second restricting element when the portable device is attached to the supporting surface, and the portable device is adapted to stand on the base by restricting a relative position of the portable device and the second restricting element.

The present invention further provides a docking station adapted to be detachably connected to a portable device. The portable device has a display surface and a first restricting element. The docking station includes a base has a supporting surface, a second restricting element disposed on the supporting surface, and a hook disposed in the second restricting element. Herein the first restricting element is latched to the hook when the portable device is attached to the supporting surface, and the portable device is adapted to stand on the base by restricting a relative position of the portable device and the second restricting element.

According to an embodiment of the present invention, the first restricting element is a protrusion and the second restricting element is a recess.

According to an embodiment of the present invention, the first restricting element is a recess and the second restricting element is a protrusion.

According to an embodiment of the present invention, the portable device has a back surface opposing the display surface, and the first restricting element is disposed on the back surface.

According to an embodiment of the present invention, the base further has a hook disposed in the second restricting element, and the first restricting element is latched to the hook when the portable device is fixed to the supporting surface.

According to an embodiment of the present invention, an edge of the portable device is inserted into the recess when the portable device is adapted to stand on the base.

According to an embodiment of the present invention, the portable device further has a groove disposed at the edge, and the groove is engaged with the hook when the portable device stands on the base.

According to an embodiment of the present invention, the docking station further comprises an input interface disposed on the base.

According to an embodiment of the present invention, the input interface is a keyboard module, a touch keyboard, or a touch panel.

In light of the above, through the second restricting element disposed on the base of the docking station of the present invention, the portable device with a good attachment to the docking station is provided. The operation convenience of the docking station and the portable device is also improved. Furthermore, the docking station of the present invention is simple in structure and low cost, since the docking station is designed without hinges, and it further makes the electronic apparatus much compact when the portable device is attached to the docking station.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates an electronic apparatus in an appearance of a portable device attached to a docking station according to an embodiment of the present invention.

FIG. 2 is the electronic apparatus in FIG. 1 illustrating the portable device stands on the docking station.

FIG. 3 illustrates the second restricting element of the docking station and the first restricting element of the portable device of the electronic apparatus in FIG. 1.

FIG. 4 is a partial enlarged view of the electronic apparatus in FIG. 1 showing the first restricting element is latched to the second restricting element.

FIG. 5 is a partial enlarged view of the electronic apparatus in FIG. 1 showing the edge of the portable device is inserted into the second restricting element.

FIG. 6 is a partial enlarged view of an electronic apparatus of another embodiment of the present invention showing the edge of the portable device is inserted into the second restricting element and the groove is engaged with the hook.

### DESCRIPTION OF THE EMBODIMENTS

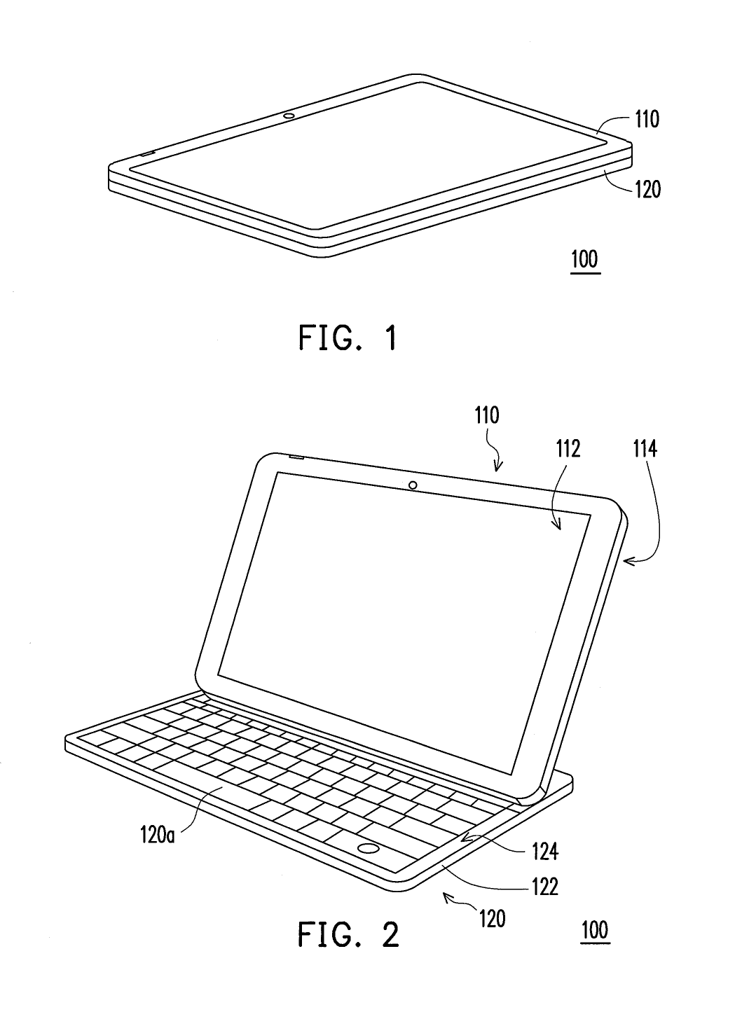

FIG. 1 illustrates an electronic apparatus in an appearance of a portable device attached to a docking station according to an embodiment of the present invention. FIG. 2 is the electronic apparatus in FIG. 1 illustrating the portable device stands on the docking station. Referring to FIG. 1 and FIG. 2, according to an embodiment of the present invention, the electronic apparatus 100 includes a portable device 110 and a docking station 120. The portable device 110 for example, is a tablet personal computer, an electronic reader or any other electronic device having a touch screen. The docking station 120 includes an input interface 120a. In the embodiment, the input interface 120a is a keyboard module as shown in FIG. 2, and in other embodiments not shown in the figures, the input interface 120a can be a touch keyboard, a touch panel or the like.

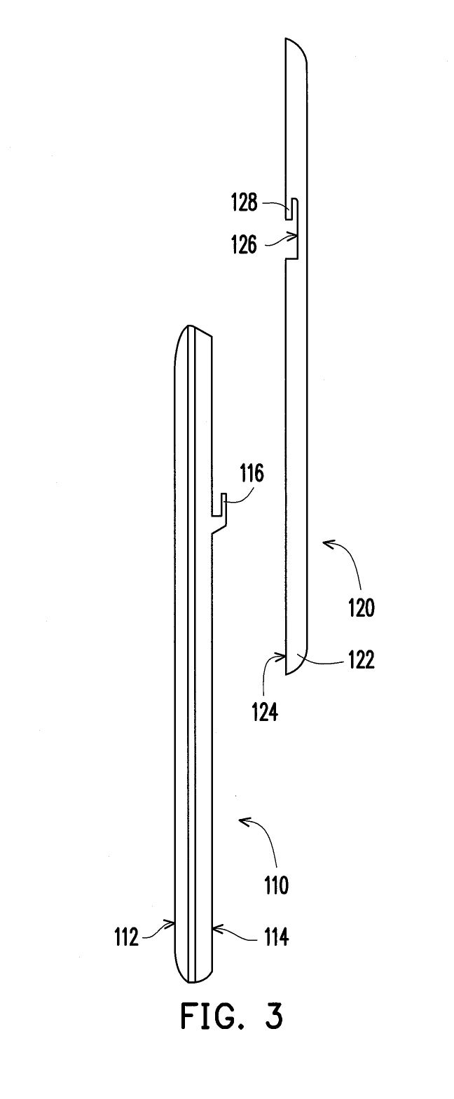

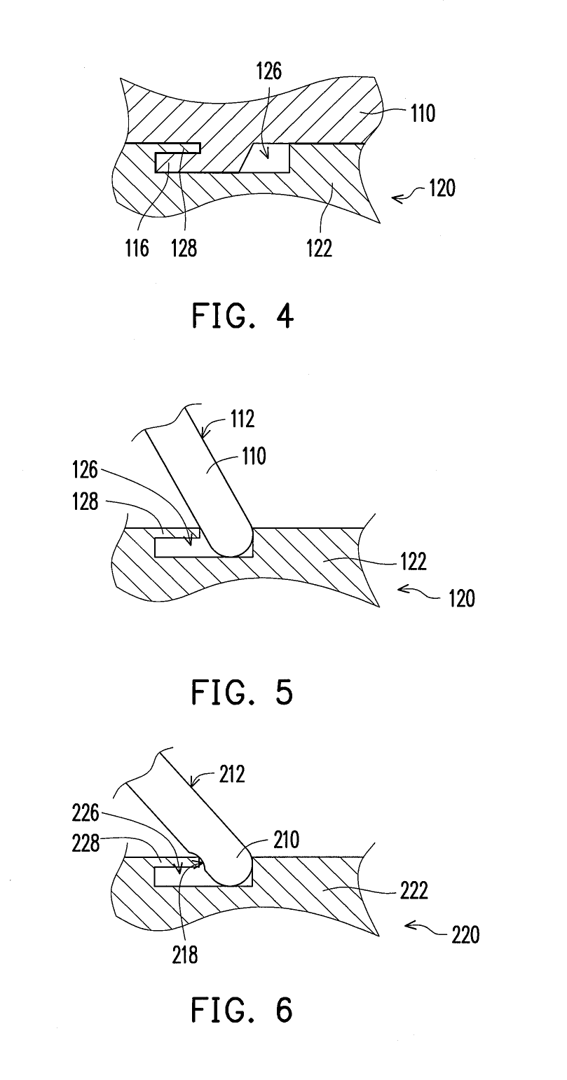

FIG. 3 illustrates the first restricting element of the portable device of the electronic apparatus and the second restricting element of the docking station in FIG. 1. FIG. 4 is a partial enlarged view of the electronic apparatus in FIG. 1 showing the first restricting element is latched to the second restricting element. Referring to FIG. 1, FIG. 3 and FIG. 4, the portable device 110 has a display surface 112, a back surface 114 opposing to the display surface 112 and a first restricting element 116 disposed on the back surface 114. The docking station 120 includes a base 122 having a supporting surface 124 and a second restricting element 126 disposed on the supporting surface 124. In the embodiment, the shape of the first restricting element 116 is designed to match with the second restricting element 126 so that the first restricting element 116 can be latched to the second restricting element 126. Accordingly, the portable device 110 can be fixed to the base 122 by latching the first restricting element 116 to the second restricting element 126 with the back surface 114 facing the supporting surface 124 of the base 122. When the portable device 110 is fixed to the base 122 through the first restricting element 116 latching in the second restricting element 126, the back surface 114 of the portable device 110 is facing the supporting surface 124 of the base 122. On the other hand, the portable device 110 can be departed from the docking station 120 by unlatching the first restricting element 116 from the second restricting element 126. It has to be noted that the first restricting element 116 can be disposed on the back surface 114 of the portable device 110 or it can be integrally formed on the back surface 114 of the portable device 110, and the present invention is not limited thereto. In the present invention, the first restricting element is a protrusion and the second restricting element is a recess and this type of the first restricting element and the second restricting element of the embodiment is not used to limit the claim scope of the present invention. Furthermore, the first restricting element also can be a recess and the second restricting element also can be a protrusion according to different product designs.

In the embodiment, in order to obtain more reliability of the fixing between the portable device 110 and the docking station 120, the second restricting element 126 of the base 122 further has a hook 128. As shown in FIG. 4, the first restricting element 116 is firmly latched in the second restricting element 126 because the first restricting element 116 is further restricted by the hook 128. The hook 128 and the second restricting element 126 can be integrally formed with the base 122, but the present invention is not limited thereto.

The electronic apparatus 100 of the embodiment is not only capable of easily fixing or departing the portable device 110 to/from the docking station 120, the portable device 110 can also stand on the base 122 of the docking station 120 by restricting the relative position of the housing of the portable device and the second restricting element. FIG. 5 is a partial enlarged view of the electronic apparatus in FIG. 1 showing the edge of the housing of the portable device is inserted into the second restricting element when the second restricting element is the recess. Referring to FIG. 2 and FIG. 5, the portable device 110 can stand on the base 122 by inserting an edge of the housing of the portable device 110 into the second restricting element 126. It should be noted that the portable device 110 can stands on the base 122 in a vertical or near vertical orientation. The included angle between the supporting surface 124 of the base 122 and the display surface 112 of the portable device 110 depends on the engagement between the second restricting element 126 and the edge of the housing of the portable device 110. Thus, in the electronic apparatus 100 of the embodiment, the portable device 110 is not only capable of fixing to the docking station 120, and the portable device 110 is adapted to stand on the base 122 in a vertical or near vertical orientation. It facilitates the user with additional operation convenience like fixing the portable device 110 to the docking station 120 so that the user can use the input interface 120a disposed on the base 122 and standing the portable device 110 onto the base 122 in a vertical or near vertical orientation so that the user can conveniently see the display surface 112.

In another embodiment, the portable device can have a groove disposed at the edge of the housing. FIG. 6 is a partial enlarged view of an electronic apparatus of another embodiment of the present invention showing the edge of the portable device is inserted into the second restricting element and the groove is engaged with the hook of the second restricting element, wherein the second restricting element is a recess. Referring to FIG. 6, in order to place the edge of the portable device 210 into the second restricting element 226 of the base 222 to let the portable device 210 stand more firmly on the base 222 of the docking station 220, a groove 218 is disposed at the edge of the portable device 210. In this embodiment, as shown in FIG. 6, the groove 218 is designed in a shape to be matched with the shape of the hook 228 or the second restricting element 226, so that the portable device 210 can stand more stably on the base 222 by inserting the edge into the second restricting element 226. In other words, the portable device 210 is further secured and firmly stood in the second restricting element 226 because of the groove 218 disposed at the edge is engaged with the hook 228 as shown in FIG. 6.

In light of the foregoing, through the second restricting element disposed on the base of the docking station of the present invention, the portable device with a good fixing to the docking station is provided. In addition, through the hook of the second restricting element provides a more firmly fixing the portable device to the base. The operation convenience of the docking station and the portable device is also improved. Furthermore, the docking station of the present invention is simple in structure and low cost, since the docking station is designed without hinges, and it further makes the electronic apparatus much compact when the portable device is attached to the docking station.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic apparatus, comprising:
a portable device having a display surface and a first restricting element; and
a docking station comprising:
a base having a supporting surface and a second restricting element disposed on the supporting surface, wherein the first restricting element is latched to the second restricting element when the portable device is attached to the supporting surface, and the portable device is adapted to stand on the base by restricting a relative position of the portable device and the second restricting element.

2. The electronic apparatus as claimed in claim 1, wherein the first restricting element is a protrusion and the second restricting element is a recess.

3. The electronic apparatus as claimed in claim 1, wherein the first restricting element is a recess and the second restricting element is a protrusion.

4. The electronic apparatus as claimed in claim 1, wherein the portable device has a back surface opposing the display surface, and the first restricting element is disposed on the back surface.

5. The electronic apparatus as claimed in claim 1, wherein the second restricting element of the base further has a hook, and the first restricting element is latched to the hook when the portable device is fixed to the supporting surface.

6. The electronic apparatus as claimed in claim 2, wherein an edge of the portable device is inserted into the recess when the portable device is adapted to stand on the base.

7. The electronic apparatus as claimed in claim 6, wherein the portable device further has a groove disposed at the edge, and the groove is engaged with the hook of the second restricting element when the portable device stands on the base.

8. The electronic apparatus as claimed in claim 1, wherein the docking station further comprises an input interface disposed on the base.

9. The electronic device as claimed in claim 8, wherein the input interface is a keyboard module, a touch keyboard, or a touch panel.

10. A docking station adapted to be detachably connected to a portable device, and the portable device having a display surface and a first restricting element, the docking station comprising:
a base having a supporting surface, and a second restricting element disposed on the supporting surface, wherein the first restricting element is latched to the second restricting element when the portable device is attached to the supporting surface, and the portable device is adapted to stand on the base by restricting a relative position of the portable device and the second restricting element.

11. The docking station as claimed in claim 10, wherein the first restricting element is a protrusion and the second restricting element is a recess.

12. The docking station as claimed in claim 10, wherein the first restricting element is a recess and the second restricting element is a protrusion.

13. The docking station as claimed in claim 10, wherein the portable device has a back surface opposing the display surface, and the first restricting element is disposed on the back surface.

14. The docking station as claimed in claim 10, wherein the second restricting element of the base further has a hook, and the first restricting element is latched to the hook when the portable device is fixed to the supporting surface.

15. The docking station as claimed in claim 11, wherein an edge of the portable device is inserted into the recess when the portable device is adapted to stand on the base.

16. The docking station as claimed in claim 15, wherein the portable device further has a groove disposed at the edge, and the groove is engaged with the hook of the second restricting element when the portable device stands on the base.

17. The docking station as claimed in claim 10, further comprising an input interface disposed on the base.

18. The docking station as claimed in claim 17, wherein the input interface is a keyboard module, a touch keyboard, or a touch panel.
